(19) United States
(12) Patent Application Publication
(10) Pub. No.: US 2024/0289507 A1
(43) Pub. Date: Aug. 29, 2024

(54) DIGITAL DESIGN FOR AUTOMATION LINE (DDFAUT-LINE) AUTOMATED ANALYSIS SYSTEM

(71) Applicant: Flex Ltd., Singapore (SG)

(72) Inventors: Jesus A. Tan, Fremont, CA (US); Murad M. Kurwa, San Jose, CA (US); Harsh R. Patil, Pleasanton, CA (US); Zohair Mehkri, Livermore, CA (US)

(73) Assignee: Flex Ltd., Singapore (SG)

(21) Appl. No.: 18/175,289

(22) Filed: Feb. 27, 2023

(51) Int. Cl. G06F 30/13

(52) U.S. Cl. CPC G06F 30/13

(57) ABSTRACT

Embodiments relate to automated review and analysis of a digital design. Performing an automated review and analysis on a three-dimensional design can comprise collecting data related to the three-dimensional design, performing a pre-processing on the three-dimensional design files and the collected data related to the three-dimensional design and performing a validation of the three-dimensional design based on a plurality of pre-defined design rules and the pre-processing of the three-dimensional design files. An analysis report can be generated based on results of performing the validation of the three-dimensional design.

### FIELD OF THE DISCLOSURE

Embodiments of the present disclosure relate generally to methods and systems for manufacturing design and more particularly to methods and systems for automated review and analysis of a digital design.

### BACKGROUND

Computer-Aided Design (CAD) is the use of computer software to aid in the creation, modification, analysis, or optimization of a design. The output of a CAD application often is in the form of electronic files for print, machining, or other manufacturing operations. Design checks can be performed on these files prior to their use in manufacturing operations. Typically, these design checks are performed manually and not structured. Therefore, these methods come with significant disadvantages. For example, a manual check is time consuming and prone to errors. Most manual checks do not follow a standard analysis process. Inconsistent check results happen due to variation in manual procedures and reliance on engineers' experience. Hence, there is a need for improved methods and systems for automated review and analysis of a digital design.

### BRIEF DESCRIPTION OF THE DRAWINGS

FIG. 1 is a block diagram illustrating elements of an exemplary computing environment in which embodiments of the present disclosure may be implemented.

FIG. 2 is a block diagram illustrating elements of an exemplary computing device in which embodiments of the present disclosure may be implemented.

FIG. 3 is a block diagram illustrating an exemplary environment in which automated design analysis may be performed according to one embodiment of the present disclosure.

FIG. 4 is a flowchart illustrating an exemplary process for performing automated design analysis according to one embodiment of the present disclosure.

FIG. 5 is a flowchart illustrating additional details of an exemplary process for generating an active component list according to one embodiment of the present disclosure.

FIG. 6 is a flowchart illustrating additional details of an exemplary process for executing a simulation according to one embodiment of the present disclosure.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the second reference label.

### DETAILED DESCRIPTION

In the following description, for the purposes of explanation, numerous specific details are set forth in order to provide a thorough understanding of various embodiments disclosed herein. It will be apparent, however, to one skilled in the art that various embodiments of the present disclosure may be practiced without some of these specific details. The ensuing description provides exemplary embodiments only and is not intended to limit the scope or applicability of the disclosure. Furthermore, to avoid unnecessarily obscuring the present disclosure, the preceding description omits a number of known structures and devices. This omission is not to be construed as a limitation of the scopes of the claims. Rather, the ensuing description of the exemplary embodiments will provide those skilled in the art with an enabling description for implementing an exemplary embodiment. It should however be appreciated that the present disclosure may be practiced in a variety of ways beyond the specific detail set forth herein.

While the exemplary aspects, embodiments, and/or configurations illustrated herein show the various components of the system collocated, certain components of the system can be located remotely, at distant portions of a distributed network, such as a Local-Area Network (LAN) and/or Wide-Area Network (WAN) such as the Internet, or within a dedicated system. Thus, it should be appreciated, that the components of the system can be combined in to one or more devices or collocated on a particular node of a distributed network, such as an analog and/or digital telecommunications network, a packet-switch network, or a circuit-switched network. It will be appreciated from the following description, and for reasons of computational efficiency, that the components of the system can be arranged at any location within a distributed network of components without affecting the operation of the system.

Furthermore, it should be appreciated that the various links connecting the elements can be wired or wireless links, or any combination thereof, or any other known or later developed element(s) that is capable of supplying and/or communicating data to and from the connected elements. These wired or wireless links can also be secure links and may be capable of communicating encrypted information. Transmission media used as links, for example, can be any suitable carrier for electrical signals, including coaxial cables, copper wire and fiber optics, and may take the form of acoustic or light waves, such as those generated during radio-wave and infra-red data communications.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material.”

The term “computer-readable medium” as used herein refers to any tangible storage and/or transmission medium that participate in providing instructions to a processor for execution. Such a medium may take many forms, including but not limited to, non-volatile media, volatile media, and transmission media. Non-volatile media includes, for example, Non-Volatile Random-Access Memory (NVRAM), or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a Compact Disk Read-Only Memory (CD-ROM), any other optical medium, punch cards, paper tape, any other physical medium with patterns of holes, a Random-Access Memory (RAM), a Programmable Read-Only Memory (PROM), and Erasable Programable Read-Only Memory (EPROM), a Flash-EPROM, a solid state medium like a memory card, any other memory chip or cartridge, a carrier wave as described hereinafter, or any other medium from which a computer can read. A digital file attachment to e-mail or other self-contained information archive or set of archives is considered a distribution medium equivalent to a tangible storage medium. When the computer-readable media is configured as a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

A “computer readable signal” medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable medium may be transmitted using any appropriate medium, including but not limited to wireless, wireline, optical fiber cable, Radio Frequency (RF), etc., or any suitable combination of the foregoing.

The terms “determine,” “calculate,” and “compute,” and variations thereof, as used herein, are used interchangeably and include any type of methodology, process, mathematical operation or technique.

It shall be understood that the term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the disclosure, brief description of the drawings, detailed description, abstract, and claims themselves.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Any combination of one or more computer readable medium(s) may be utilized. The computer readable medium may be a computer readable signal medium or a computer readable storage medium.

In yet another embodiment, the systems and methods of this disclosure can be implemented in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as Programmable Logic Device (PLD), Programmable Logic Array (PLA), Field Programmable Gate Array (FPGA), Programmable Array Logic (PAL), special purpose computer, any comparable means, or the like. In general, any device(s) or means capable of implementing the methodology illustrated herein can be used to implement the various aspects of this disclosure. Exemplary hardware that can be used for the disclosed embodiments, configurations, and aspects includes computers, handheld devices, telephones (e.g., cellular, Internet enabled, digital, analog, hybrids, and others), and other hardware known in the art. Some of these devices include processors (e.g., a single or multiple microprocessors), memory, nonvolatile storage, input devices, and output devices. Furthermore, alternative software implementations including, but not limited to, distributed processing or component/object distributed processing, parallel processing, or virtual machine processing can also be constructed to implement the methods described herein.

Examples of the processors as described herein may include, but are not limited to, at least one of Qualcomm® Snapdragon® 800 and 801, Qualcomm® Snapdragon® 610 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22nm Haswell, Intel® Core® i5-3570K 22nm Ivy Bridge, the AMD® FX™ family of processors, AMD® FX-4300, FX-6300, and FX-8350 32nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

In yet another embodiment, the disclosed methods may be readily implemented in conjunction with software using object or object-oriented software development environments that provide portable source code that can be used on a variety of computer or workstation platforms. Alternatively, the disclosed system may be implemented partially or fully in hardware using standard logic circuits or Very Large-Scale Integration (VLSI) design. Whether software or hardware is used to implement the systems in accordance with this disclosure is dependent on the speed and/or efficiency requirements of the system, the particular function, and the particular software or hardware systems or microprocessor or microcomputer systems being utilized.

In yet another embodiment, the disclosed methods may be partially implemented in software that can be stored on a storage medium, executed on programmed general-purpose computer with the cooperation of a controller and memory, a special purpose computer, a microprocessor, or the like. In these instances, the systems and methods of this disclosure can be implemented as program embedded on personal computer such as an applet, JAVA® or Common Gateway Interface (CGI) script, as a resource residing on a server or computer workstation, as a routine embedded in a dedicated measurement system, system component, or the like. The system can also be implemented by physically incorporating the system and/or method into a software and/or hardware system.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein and other similar standards and protocols not mentioned herein are periodically superseded by faster or more effective equivalents having essentially the same functions. Such replacement standards and protocols having the same functions are considered equivalents included in the present disclosure.

Various additional details of embodiments of the present disclosure will be described below with reference to the figures. While the flowcharts will be discussed and illustrated in relation to a particular sequence of events, it should be appreciated that changes, additions, and omissions to this sequence can occur without materially affecting the operation of the disclosed embodiments, configuration, and aspects.

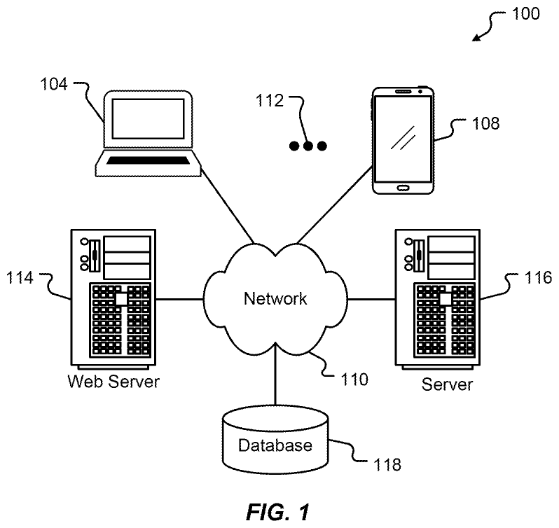

FIG. 1 is a block diagram illustrating elements of an exemplary computing environment in which embodiments of the present disclosure may be implemented. More specifically, this example illustrates a computing environment 100 that may function as the servers, user computers, or other systems provided and described herein. The environment 100 includes one or more user computers, or computing devices, such as a computing device 104, a communication device 108, and/or more 112. The computing devices 104, 108, 112 may include general purpose personal computers (including, merely by way of example, personal computers, and/or laptop computers running various versions of Microsoft Corp.'s Windows® and/or Apple Corp.'s Macintosh® operating systems) and/or workstation computers running any of a variety of commercially-available UNIX® or UNIX-like operating systems. These computing devices 104, 108, 112 may also have any of a variety of applications, including for example, database client and/or server applications, and web browser applications. Alternatively, the computing devices 104, 108, 112 may be any other electronic device, such as a thin-client computer, Internet-enabled mobile telephone, and/or personal digital assistant, capable of communicating via a network 110 and/or displaying and navigating web pages or other types of electronic documents. Although the exemplary computer environment 100 is shown with two computing devices, any number of user computers or computing devices may be supported.

Environment 100 further includes a network 110. The network 110 may can be any type of network familiar to those skilled in the art that can support data communications using any of a variety of commercially-available protocols, including without limitation Session Initiation Protocol (SIP), Transmission Control Protocol/Internet Protocol (TCP/IP), Systems Network Architecture (SNA), Internetwork Packet Exchange (IPX), AppleTalk, and the like. Merely by way of example, the network 110 maybe a Local Area Network (LAN), such as an Ethernet network, a Token-Ring network and/or the like; a wide-area network; a virtual network, including without limitation a Virtual Private Network (VPN); the Internet; an intranet; an extranet; a Public Switched Telephone Network (PSTN); an infra-red network; a wireless network (e.g., a network operating under any of the IEEE 802.9 suite of protocols, the Bluetooth® protocol known in the art, and/or any other wireless protocol); and/or any combination of these and/or other networks.

The system may also include one or more servers 114, 116. In this example, server 114 is shown as a web server and server 116 is shown as an application server. The web server 114, which may be used to process requests for web pages or other electronic documents from computing devices 104, 108, 112. The web server 114 can be running an operating system including any of those discussed above, as well as any commercially-available server operating systems. The web server 114 can also run a variety of server applications, including SIP servers, HyperText Transfer Protocol (secure) (HTTP(s)) servers, FTP servers, CGI servers, database servers, Java servers, and the like. In some instances, the web server 114 may publish operations available operations as one or more web services.

The environment 100 may also include one or more file and or/application servers 116, which can, in addition to an operating system, include one or more applications accessible by a client running on one or more of the computing devices 104, 108, 112. The server(s) 116 and/or 114 may be one or more general purpose computers capable of executing programs or scripts in response to the computing devices 104, 108, 112. As one example, the server 116, 114 may execute one or more web applications. The web application may be implemented as one or more scripts or programs written in any programming language, such as Java™, C, C #®, or C++, and/or any scripting language, such as Perl, Python, or Tool Command Language (TCL), as well as combinations of any programming/scripting languages. The application server(s) 116 may also include database servers, including without limitation those commercially available from Oracle®, Microsoft®, Sybase®, IBM® and the like, which can process requests from database clients running on a computing device 104, 108, 112.

The web pages created by the server 114 and/or 116 may be forwarded to a computing device 104, 108, 112 via a web (file) server 114, 116. Similarly, the web server 114 may be able to receive web page requests, web services invocations, and/or input data from a computing device 104, 108, 112 (e.g., a user computer, etc.) and can forward the web page requests and/or input data to the web (application) server 116. In further embodiments, the server 116 may function as a file server. Although for ease of description, FIG. 1 illustrates a separate web server 114 and file/application server 116, those skilled in the art will recognize that the functions described with respect to servers 114, 116 may be performed by a single server and/or a plurality of specialized servers, depending on implementation-specific needs and parameters. The computer systems 104, 108, 112, web (file) server 114 and/or web (application) server 116 may function as the system, devices, or components described herein.

The environment 100 may also include a database 118. The database 118 may reside in a variety of locations. By way of example, database 118 may reside on a storage medium local to (and/or resident in) one or more of the computers 104, 108, 112, 114, 116. Alternatively, it may be remote from any or all of the computers 104, 108, 112, 114, 116, and in communication (e.g., via the network 110) with one or more of these. The database 118 may reside in a Storage-Area Network (SAN) familiar to those skilled in the art. Similarly, any necessary files for performing the functions attributed to the computers 104, 108, 112, 114, 116 may be stored locally on the respective computer and/or remotely, as appropriate. The database 118 may be a relational database, such as Oracle 20i®, that is adapted to store, update, and retrieve data in response to Structured Query Language (SQL) formatted commands.

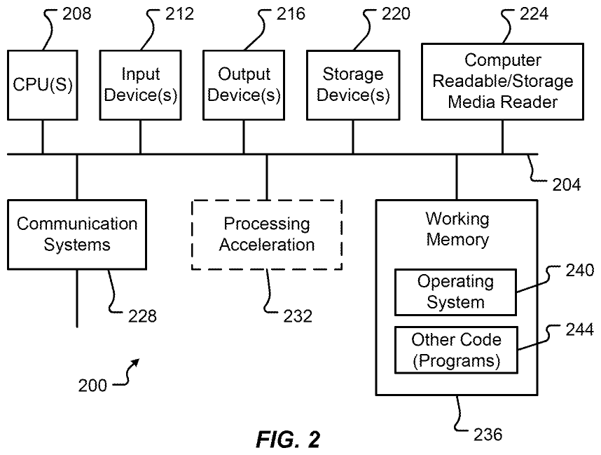

FIG. 2 is a block diagram illustrating elements of an exemplary computing device in which embodiments of the present disclosure may be implemented. More specifically, this example illustrates one embodiment of a computer system 200 upon which the servers, user computers, computing devices, or other systems or components described above may be deployed or executed. The computer system 200 is shown comprising hardware elements that may be electrically coupled via a bus 204. The hardware elements may include one or more Central Processing Units (CPUs) 208; one or more input devices 212 (e.g., a mouse, a keyboard, etc.); and one or more output devices 216 (e.g., a display device, a printer, etc.). The computer system 200 may also include one or more storage devices 220. By way of example, storage device(s) 220 may be disk drives, optical storage devices, solid-state storage devices such as a Random-Access Memory (RAM) and/or a Read-Only Memory (ROM), which can be programmable, flash-updateable and/or the like.

The computer system 200 may additionally include a computer-readable storage media reader 224; a communications system 228 (e.g., a modem, a network card (wireless or wired), an infra-red communication device, etc.); and working memory 236, which may include RAM and ROM devices as described above. The computer system 200 may also include a processing acceleration unit 232, which can include a Digital Signal Processor (DSP), a special-purpose processor, and/or the like.

The computer-readable storage media reader 224 can further be connected to a computer-readable storage medium, together (and, optionally, in combination with storage device(s) 220) comprehensively representing remote, local, fixed, and/or removable storage devices plus storage media for temporarily and/or more permanently containing computer-readable information. The communications system 228 may permit data to be exchanged with a network and/or any other computer described above with respect to the computer environments described herein. Moreover, as disclosed herein, the term “storage medium” may represent one or more devices for storing data, including ROM, RAM, magnetic RAM, core memory, magnetic disk storage mediums, optical storage mediums, flash memory devices and/or other machine-readable mediums for storing information.

The computer system 200 may also comprise software elements, shown as being currently located within a working memory 236, including an operating system 240 and/or other code 244. It should be appreciated that alternate embodiments of a computer system 200 may have numerous variations from that described above. For example, customized hardware might also be used and/or particular elements might be implemented in hardware, software (including portable software, such as applets), or both. Further, connection to other computing devices such as network input/output devices may be employed.

Examples of the processors 208 as described herein may include, but are not limited to, at least one of Qualcomm® Snapdragon® 800 and 801, Qualcomm® Snapdragon® 620 and 615 with 4G LTE Integration and 64-bit computing, Apple® A7 processor with 64-bit architecture, Apple® M7 motion coprocessors, Samsung® Exynos® series, the Intel® Core™ family of processors, the Intel® Xeon® family of processors, the Intel® Atom™ family of processors, the Intel Itanium® family of processors, Intel® Core® i5-4670K and i7-4770K 22nm Haswell, Intel® Core® i5-3570K 22nm Ivy Bridge, the AMD® FX™ family of processors, AMD® FX-4300, FX-6300, and FX-8350 32nm Vishera, AMD® Kaveri processors, Texas Instruments® Jacinto C6000™ automotive infotainment processors, Texas Instruments® OMAP™ automotive-grade mobile processors, ARM® Cortex™-M processors, ARM® Cortex-A and ARM926EJ-S™ processors, other industry-equivalent processors, and may perform computational functions using any known or future-developed standard, instruction set, libraries, and/or architecture.

Embodiments describe an automated system for performing design rule checks and mechanical part & assembly automation readiness checks. The system can use a custom application to start the analysis, input three-dimensional part and assembly files and view the completed analysis result in user readable format. The system can use a design rule database, containing various automation design rules, structured by part type, assembly type, assembly location, feature type, assembly process, automation machine type, material and similar attributes associated with automated manufacturing assembly process and three-dimensional part and assembly files. The system can use another application to perform the three-dimensional design analysis based on pre-defined custom analysis checklist against the design rules in the design rule database previously mentioned. Additional details of such a system are provided in Appendix A submitted herewith and incorporated herein by reference.

Embodiments utilize and establish a structured and automated design rule check, driving each analysis check based on established rule database, perform custom design analysis in three-dimensional part and assemblies, and visualizing the analysis result in user readable formats. Embodiments provide dynamic and standardized process based on product three-dimensional files and defined automation process. Embodiments provide consistent result analysis due to use of dynamic rules database covering multiple three-dimensional part and assembly and automation assembly attributes. Embodiments provide validation of product assembly for automated assemblies using robotic and associated components of automation.

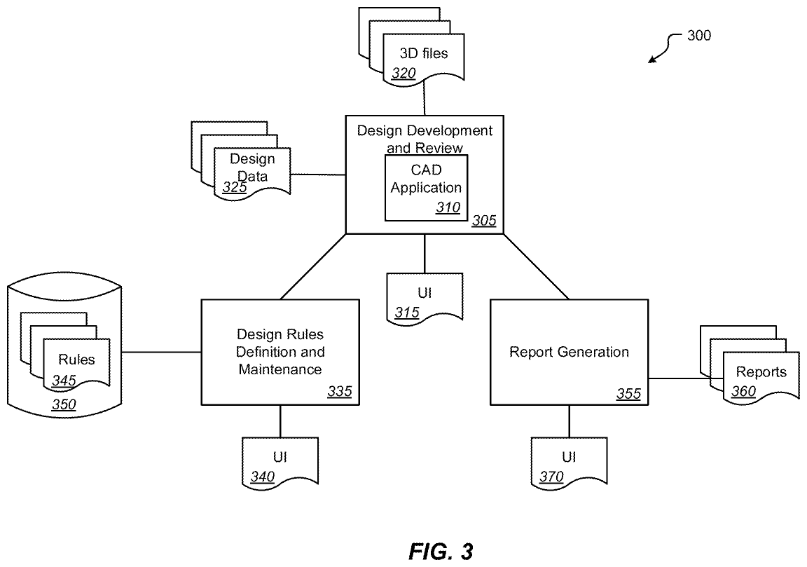

FIG. 3 is a block diagram illustrating an exemplary environment in which automated design analysis may be performed according to one embodiment of the present disclosure. As illustrated in this example, the environment 300 can include a design development and review component 305. The design development and review component can be any one or more servers and/or other computing devices as described above. The design development and review component can execute a three-dimensional Computer-Aided Design (CAD) application 310. As known in the art, the three-dimensional CAD application can present a user interface 315 through which a user may define, view, modify, etc. any number of digital designs defined in a set of three-dimensional design files 320. Similarly, the three-dimensional CAD application may generate and/or maintain a set of design data 325 for specifications and/or requirements related to the design.

The environment can also include a design rules definition and maintenance component 335. The design rules definition and maintenance component 335 can comprise one or more servers and/or other computing devices as described above. While shown here as separate from the design development and review component 305 for the sake of illustration, the design rules definition and maintenance component 335 may be implemented on the same or different physical and/or virtual machines as the design development and review component 305. The design rules definition and maintenance component 335 can present a user interface 340 through which a user can define a set of design rules 345 maintained by the design rules definition and maintenance component 335 in a rules database 350.

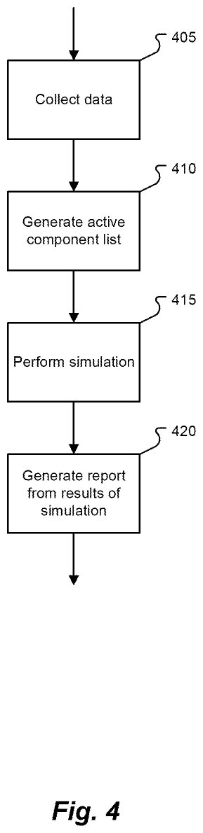

Generally speaking, an automated review and analysis on a three-dimensional design can be performed by collecting design data 325 related to a three-dimensional design. This data 325 can include, but is not limited to, component data for the components, e.g., component type, technical specifications, geometric properties, one or more three-dimensional CAD files 320, etc., one or more assembly rules defining, for example, assembly steps, component specific assembly rules, relationships between components, etc., and supplier information for components, e.g., price, manufacturing information, etc. An active component list for the three-dimensional design can be generated by the design development and review component 305 using the collected data. The active component list can comprise a Bill Of Materials (BOM) for the three-dimensional design. An assembly simulation for the three-dimensional design can be performed by the design development and review component 305 based on the generated active component list and the collected data related to the three-dimensional design. An analysis report 360 can be generated by the report generation component 355 based on results of executing the assembly simulation for the three-dimensional design. The reports may be viewable through a user interface 370 provided by the report generation component 355. In some cases, a Virtual Reality (VR) presentation of the assembly simulation can additionally, or alternatively, be presented, e.g., by the CAD application 310 through the user interface 315 of the design development and review component 305. Additional details of exemplary processes for performing an automated review and analysis on a three-dimensional design will be described below with reference to FIGS. 4-6.

FIG. 4 is a flowchart illustrating an exemplary process for performing automated design analysis according to one embodiment of the present disclosure. As illustrated in this example, performing an automated review and analysis on a three-dimensional design can begin with collecting 405 data related to a three-dimensional design. This data can include, but is not limited to, component data for the components, e.g., component type, technical specifications, geometric properties, one or more three-dimensional CAD files, etc., one or more assembly rules defining, for example, assembly steps, component specific assembly rules, relationships between components, etc., and supplier information for components, e.g., price, manufacturing information, etc.

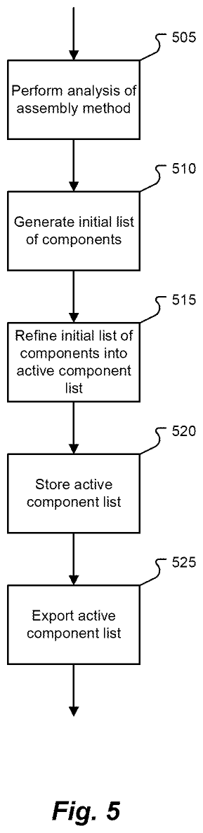

An active component list for the three-dimensional design can be generated 410 using the collected 405 data. The active component list can comprise a BOM for the three-dimensional design. Additional details of an exemplary process for generating 410 an active component list for the three-dimensional design will be described below with reference to FIG. 5

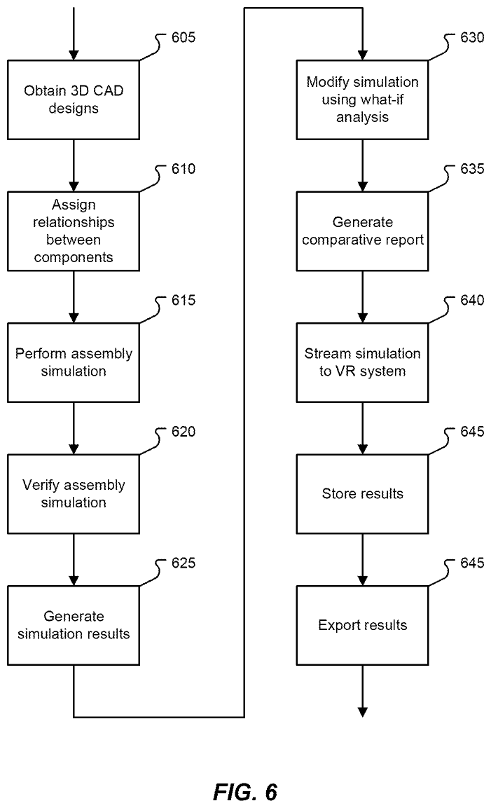

An assembly simulation for the three-dimensional design can be performed 415 based on the generated active component list and the collected data related to the three-dimensional design. Additional details of an exemplary process for performing 415 an assembly simulation for the three-dimensional design will be described below with reference to FIG. 6. An analysis report generated 420 based on results of executing the assembly simulation for the three-dimensional design.

FIG. 5 is a flowchart illustrating additional details of an exemplary process for generating an active component list according to one embodiment of the present disclosure. As illustrated in this example, generating an active component list for a three-dimensional design can begin with performing 505 an analysis of an assembly method defined by the collected data related to the three-dimensional design and generating 510 an initial list of components for the three-dimensional design based on the analysis of the assembly methods. For example, one or more assembly methods can be defined for any number of components in one or more rules in the collected data. The initial list of components can include all possible components for an assembly, i.e., including alternatives or replacements etc.

The initial list of components for the three-dimensional design can be refined 515 to generate the active component list for the three-dimensional design. Refining 515 the initial list of components can comprise one or more automatic processes such as applying one or more predefined rules to select components from the initial list of components, one or more manual processes such as receiving a user selection of components from the initial list of components, or a combination thereof. The active component list for the three-dimensional design can then be saved 520. In some cases, generating the active component list for the three-dimensional design can further comprise exporting 525 the active component list for the three-dimensional design, e.g., to a format usable by another system, on another platform, etc.

FIG. 6 is a flowchart illustrating additional details of an exemplary process for performing a simulation according to one embodiment of the present disclosure. As illustrated in this example, performing the assembly simulation for the three-dimensional design can begin with obtaining 605 one or more three-dimensional CAD files for each component of the active component list for the three-dimensional design and assigning 610 relationships between components of the active component list based on the obtained three-dimensional CAD files and collected data related to the three-dimensional design, e.g., one or more rules defining relationships between components.

An assembly simulation can be performed 615 using the obtained three-dimensional CAD files and the assigned relationships between the components of the active component list. Upon completion, the assembly simulation can be verified 620 based on the collected data related to the three-dimensional design, e.g., based on one or more rules defined for assembly of the three-dimensional design and/or other automation information for assembly of the three-dimensional design. A set of simulation results for the assembly simulation can then be generated 625 based on verifying the assembly simulation.

In some cases, performing the assembly simulation for the three-dimensional design can further comprise modifying 630 the assembly simulation using a what-if analysis. In such cases, a comparative report can be generated 635 for the modified assembly simulation i.e., comparing the modified assemble simulation to the initial, unmodified assembly simulation. According to one embodiment, a VR representation of the assembly simulation can be streamed. Results of the assembly simulation and/or modified assembly simulation can be saved 645 and, in some cases, the results of the assembly simulation and/or modified assembly simulation can be exported 645, e.g., to a format usable by another system, on another platform, etc.

The present disclosure, in various aspects, embodiments, and/or configurations, includes components, methods, processes, systems, and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A method for performing an automated review and analysis on a three-dimensional design, the method comprising:
collecting, by a processor of the design development and review system, data related to a three-dimensional design;
generating, by the processor of the design development and review system, an active component list for the three-dimensional design, wherein the active component list comprises a Bill Of Materials (BOM) for the three-dimensional design;
performing, by the processor of the design development and review system, an assembly simulation for the three-dimensional design based on the generated active component list and the collected data related to the three-dimensional design; and
generating, by the processor of the design development and review system, an analysis report based on results of executing the assembly simulation for the three-dimensional design.

2. The method of claim 1, wherein generating the active component list for the three-dimensional design comprises:
performing an analysis of an assembly methods defined by the collected data related to the three-dimensional design;
generating an initial list of components for the three-dimensional design based on the analysis of the assembly methods;
refining the initial list of components for the three-dimensional design to generate the active component list for the three-dimensional design; and
storing the active component list for the three-dimensional design.

3. The method of claim 2, wherein generating the active component list for the three-dimensional design further comprises exporting the active component list for the three-dimensional design.

4. The method of claim 1, wherein performing the assembly simulation for the three-dimensional design comprises:
obtaining one or more three-dimensional Computer Aided Design (CAD) files for each component of the active component list for the three-dimensional design;
assigning relationships between components of the active component list based on the obtained three-dimensional CAD files and collected data related to the three-dimensional design;
performing an assembly simulation using the obtained three-dimensional CAD files and the assigned relationships between the components of the active component list;
verifying the assembly simulation based on the collected data related to the three-dimensional design; and
generating a set of simulation results for the assembly simulation based on verifying the assembly simulation.

5. The method of claim 4, wherein performing the assembly simulation for the three-dimensional design further comprises modifying the assembly simulation using a what-if analysis.

6. The method of claim 5, wherein performing the assembly simulation for the three-dimensional design further comprises generating a comparative report for the modified assembly simulation.

7. The method of claim 4, wherein performing the assembly simulation for the three-dimensional design further comprises streaming a Virtual Reality (VR) representation of the assembly simulation.

8. The method of claim 4, wherein performing the assembly simulation for the three-dimensional design further comprises exporting the generated set of simulation results.

9. A system comprising:
a processor; and
a memory coupled with and readable by the processor and storing therein a set of instructions which, when executed by the processor, causes the processor to perform an automated review and analysis on a three-dimensional design by:
collecting data related to a three-dimensional design;
generating an active component list for the three-dimensional design, wherein the active component list comprises a Bill Of Materials (BOM) for the three-dimensional design;
performing an assembly simulation for the three-dimensional design based on the generated active component list and the collected data related to the three-dimensional design; and
generating an analysis report based on results of executing the assembly simulation for the three-dimensional design.

10. The system of claim 9, wherein generating the active component list for the three-dimensional design comprises:
performing an analysis of an assembly methods defined by the collected data related to the three-dimensional design;
generating an initial list of components for the three-dimensional design based on the analysis of the assembly methods;
refining the initial list of components for the three-dimensional design to generate the active component list for the three-dimensional design; and
storing the active component list for the three-dimensional design.

11. The system of claim 9, wherein performing the assembly simulation for the three-dimensional design comprises:
obtaining one or more three-dimensional Computer Aided Design (CAD) files for each component of the active component list for the three-dimensional design;
assigning relationships between components of the active component list based on the obtained three-dimensional CAD files and collected data related to the three-dimensional design;
performing an assembly simulation using the obtained three-dimensional CAD files and the assigned relationships between the components of the active component list;
verifying the assembly simulation based on the collected data related to the three-dimensional design; and
generating a set of simulation results for the assembly simulation based on verifying the assembly simulation.

12. The system of claim 11, wherein performing the assembly simulation for the three-dimensional design further comprises modifying the assembly simulation using a what-if analysis.

13. The system of claim 12, wherein performing the assembly simulation for the three-dimensional design further comprises generating a comparative report for the modified assembly simulation.

14. The system of claim 11, wherein performing the assembly simulation for the three-dimensional design further comprises streaming a Virtual Reality (VR) representation of the assembly simulation.

15. A non-transitory, computer readable medium comprising a set of instructions which, when executed by a processor, causes the processor to perform an automated review and analysis on a three-dimensional design by:
collecting data related to a three-dimensional design;
generating an active component list for the three-dimensional design, wherein the active component list comprises a Bill Of Materials (BOM) for the three-dimensional design;
performing an assembly simulation for the three-dimensional design based on the generated active component list and the collected data related to the three-dimensional design; and
generating an analysis report based on results of executing the assembly simulation for the three-dimensional design.

16. The non-transitory, computer readable medium of claim 15, wherein generating the active component list for the three-dimensional design comprises:
performing an analysis of an assembly methods defined by the collected data related to the three-dimensional design;
generating an initial list of components for the three-dimensional design based on the analysis of the assembly methods;
refining the initial list of components for the three-dimensional design to generate the active component list for the three-dimensional design; and
storing the active component list for the three-dimensional design.

17. The non-transitory, computer readable medium of claim 15, wherein performing the assembly simulation for the three-dimensional design comprises:
obtaining one or more three-dimensional Computer Aided Design (CAD) files for each component of the active component list for the three-dimensional design;
assigning relationships between components of the active component list based on the obtained three-dimensional CAD files and collected data related to the three-dimensional design;
performing an assembly simulation using the obtained three-dimensional CAD files and the assigned relationships between the components of the active component list;
verifying the assembly simulation based on the collected data related to the three-dimensional design; and
generating a set of simulation results for the assembly simulation based on verifying the assembly simulation.

18. The non-transitory, computer readable medium of claim 17, wherein performing the assembly simulation for the three-dimensional design further comprises modifying the assembly simulation using a what-if analysis.

19. The non-transitory, computer readable medium of claim 18, wherein performing the assembly simulation for the three-dimensional design further comprises generating a comparative report for the modified assembly simulation.

20. The non-transitory, computer readable medium of claim 117, wherein performing the assembly simulation for the three-dimensional design further comprises streaming a Virtual Reality (VR) representation of the assembly simulation.
